(19) United States
(12) Patent Application Publication
(10) Pub. No.: US 2024/0030265 A1
(43) Pub. Date: Jan. 25, 2024

(54) STACKED CHIP SCALE OPTICAL SENSOR PACKAGE

(71) Applicant: SEMICONDUCTOR COMPONENTS INDUSTRIES, LLC, Phoenix, AZ (US)

(72) Inventor: Weng-Jin WU, Hsinchu City (TW)

(73) Assignee: SEMICONDUCTOR COMPONENTS INDUSTRIES, LLC, Phoenix, AZ (US)

(21) Appl. No.: 17/813,972

(22) Filed: Jul. 21, 2022

(51) Int. Cl. H01L 27/146; H01L 23/00

(52) U.S. Cl. CPC H01L 27/14632; H01L 24/24; H01L 27/14687; H01L 27/1469; H01L 27/14634; H01L 27/14636; H01L 27/14645; H01L 24/29; H01L 24/32; H01L 24/83; H01L 24/82; H01L 2224/244; H01L 2224/2919; H01L 2924/0665; H01L 2224/82007; H01L 2224/32225; H01L 2224/29016; H01L 2224/8203; H01L 2224/83862; H01L 2224/24146; H01L 2224/73267; H01L 24/73; H01L 2224/92244; H01L 24/92; H01L 2224/94; H01L 2224/97; H01L 24/97; H01L 24/94

(57) ABSTRACT

In a general aspect, a package includes an optical sensor die fabricated in a semiconductor wafer. The optical sensor die has an optically active area on a front side of the semiconductor wafer generating a raw image signal. A transparent cover attached to the front side of the semiconductor wafer above the optically active area of the optical sensor die. An image signal processor (ISP) die processing the raw image signal is embedded in a layer of molding material attached to a back side the semiconductor wafer opposite the front side of the semiconductor wafer.

### TECHNICAL FIELD

This description relates to packaging of semiconductor optical sensors.

### BACKGROUND

Digital image sensors (e.g., a complementary metal-oxide-semiconductor image sensor (CIS) or a charge-coupled device (CCD)) are typically packaged as single die in an integrated circuit (IC) package (i.e., a ceramic ball grid array package (CBGA) or a plastic ball grid array (PBGA) package. However, newer applications (e.g., automotive applications such as advanced driver assistance systems (ADAS) and autonomous driving (AD) systems) need other circuitry (e.g., image signal processor (ISP) or ASIC die) to be included in the same IC package as the CIS die for improved imaging performance.

### SUMMARY

In a general aspect, a package includes an optical sensor die fabricated in a semiconductor wafer. The optical sensor die has an optically active area on a front side of the semiconductor wafer generating a raw image signal. A transparent cover is attached to the front side of the semiconductor wafer above the optically active area of the optical sensor die. An image signal processor (ISP) die processing the raw image signal is embedded in a layer of molding material attached to a back side the semiconductor wafer opposite the front side of the semiconductor wafer.

In a general aspect, a method includes attaching a semiconductor wafer to a sheet of transparent material. The semiconductor wafer includes a plurality of optical sensor dies. The method further includes attaching a plurality of individual image signal processor (ISP) dies to back surfaces of the plurality of the optical sensor dies in the semiconductor wafer, embedding the plurality of the individual ISP dies attached to the back surfaces of the plurality of the optical sensor dies in a wafer-level molding layer, and singulating a wafer-level assembly of the sheet of the transparent material attached to the semiconductor wafer and the wafer-level molding layer to produce at least one individual stacked optical sensor package.

The details of one or more implementations are set forth in the accompanying drawings and the description below. Other features will be apparent from the description and drawings, and from the claims.

### BRIEF DESCRIPTION OF THE DRAWINGS

FIG. 1A schematically illustrates an example stacked optical sensor package.

FIG. 1B schematically illustrates an example gapless stacked optical sensor package.

FIG. 1C schematically illustrates another example stacked optical sensor package.

FIG. 1D schematically illustrates yet another example stacked optical sensor package.

FIG. 1E schematically illustrates a further example stacked optical sensor package.

FIG. 2 illustrates an example method for fabricating a stacked chip scale optical sensor package.

FIGS. 3A through 3K illustrate cross-sectional views of a stacked optical sensor package at different stages of construction.

### DETAILED DESCRIPTION

An optical sensor (e.g., a RGB visible light image sensor of a camera, an image sensor) is configured for converting a radiation intensity and color spectrum into electrical signals. In some implementations, optical sensors (including, e.g., digital image sensors) can be devices for detecting light intensity. In some implementations, an optical sensor can produce an electrical output. The raw image (RAW) data generated by the optical sensor may, for example, be in the form of zeroes and ones for each pixel of the optical sensor array. An image signal processor (ISP) is a dedicated processor that converts the RAW data generated by the optical sensor into a workable image output through various signal conditioning processes. These various signal conditioning processes may, for example, include one or more of noise reduction, lens shading correction, gamma correction, auto exposure, or auto white balance, etc.

This disclosure describes multi-die optical sensor packages and methods for fabricating the multi-die optical sensor packages. An example multi-die optical sensor package may, for example, be a stacked wafer-level chip scale package (CSP). In a stacked optical sensor CSP, a digital image sensor die (e.g., a complementary metal— oxide—semiconductor image sensor (CIS) die, or a charge-coupled device (CCD) die) is arranged in a stack with an image signal processor (ISP) die. The stacked optical sensor CSP includes a transparent window, cover, or lid over the stack of the optical sensor die and the ISP die. In example implementations, the stacked optical sensor CSP is fabricated as a wafer-level chip scale package (WL-CSP), for example, with the top and bottom outer layers of the packaging and solder bumps attached to the package while the optical sensor dies are still in the wafer, and then dicing the wafer.

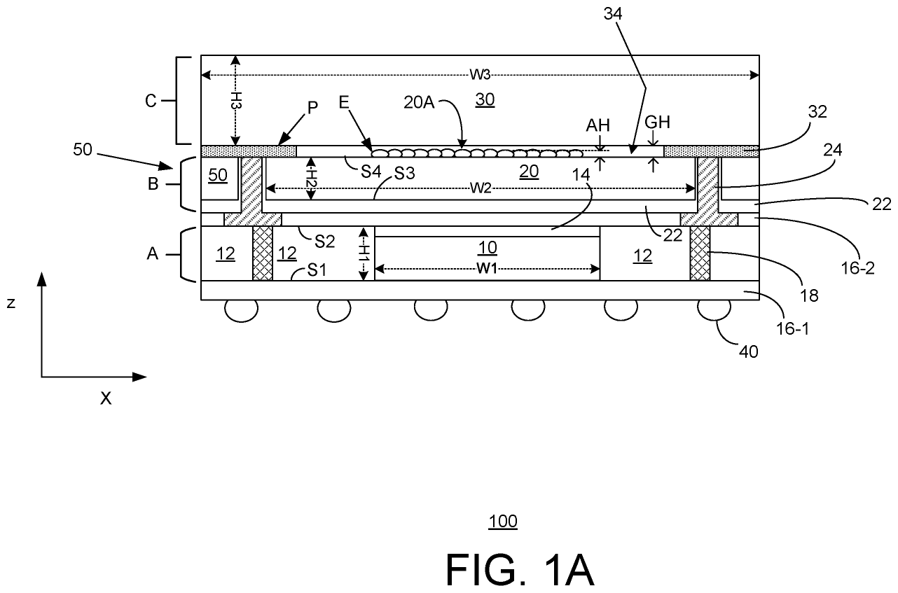

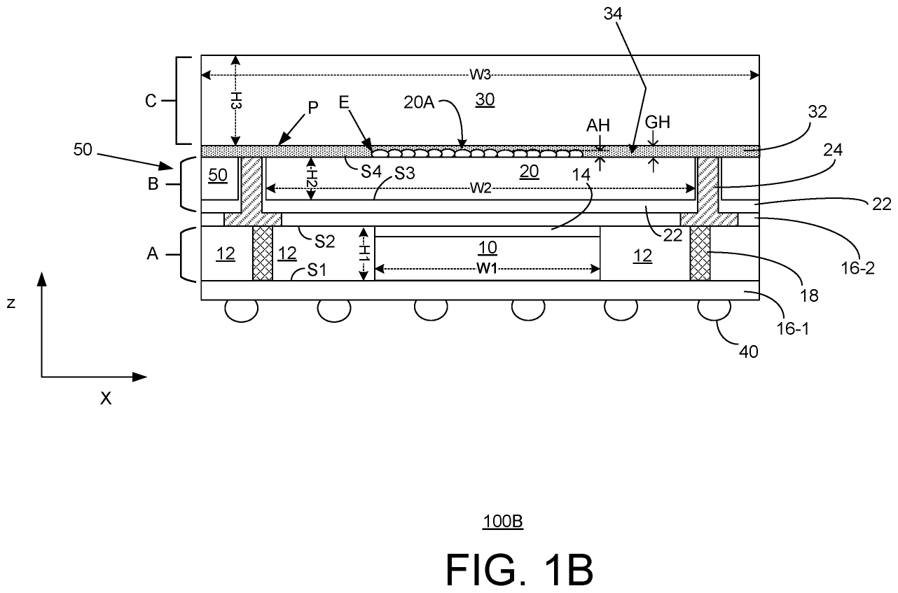

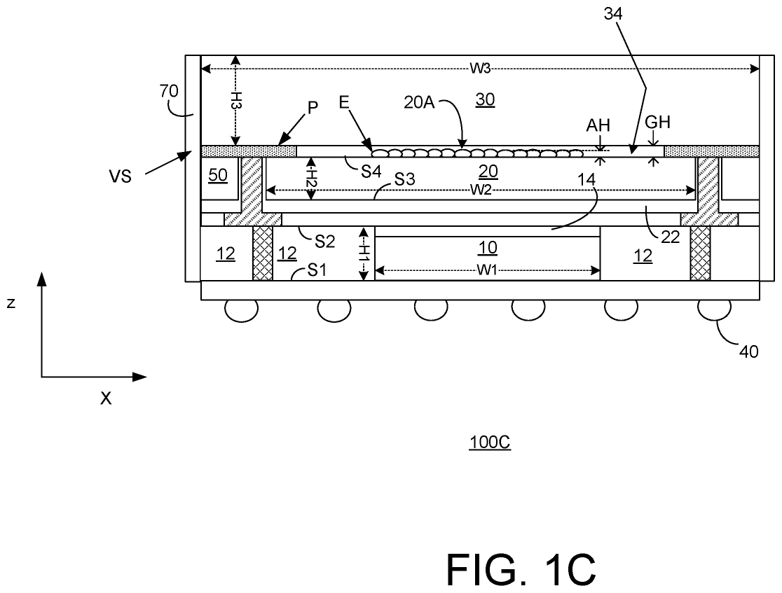

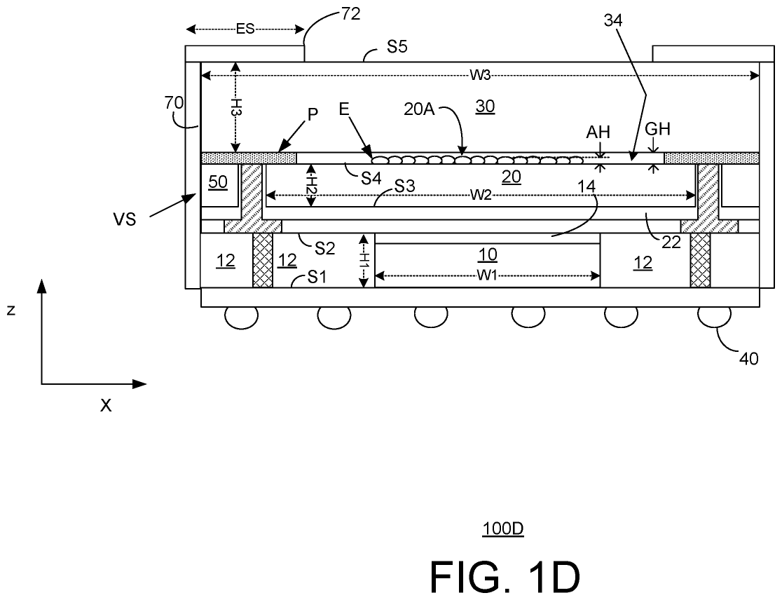

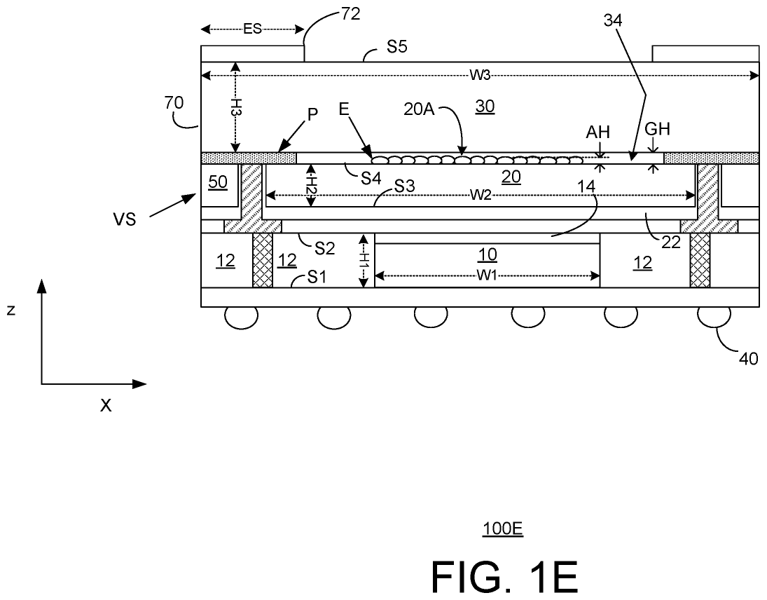

FIG. 1A schematically illustrates an example stacked optical sensor package 100. Optical sensor package may be fabricated, for example, as a WL-CSP in accordance with the principles of the present disclosure.

As shown in FIG. 1A, stacked optical sensor package 100 processed as a WL-CSP may include ISP die (e.g., ISP die 10), a wafer 50 including optical sensor dies (e.g., optical sensor die 20), and a sheet of a transparent material (e.g., cover glass 30) disposed in layers A, B and C, respectively, of the package. Layers A, B and C may be disposed in sequence one on top of another (in the z direction), for example, with layer C on top of layer B, and layer B on top of layer A.

Layer A may include ISP die 10 embedded in a layer of molding material 12. ISP die 10 may have a width W1 (in the x direction) and a height H1 (in the z direction). A first redistribution layer (e.g., RDL 16-1) may be disposed on a first surface (e.g., surface S1) of layer A, and a second redistribution layer ISP (e.g., RDL 16-2) may be disposed on a second surface (e.g., surface S2) of layer A. The first surface (e.g., surface S1) of layer A may be the outer surface (bottom surface) of stacked optical sensor package 100. The second surface (e.g., surface S2) of layer A may be an inner surface of stacked optical sensor package 100 next to layer B. The redistribution layers (e.g., RDL 16-1, RDL 16-2) may be made of metal or metal alloy and may include circuit traces and contact pads (not shown) for electrical connection to the dies in stacked optical sensor package 100. Further, in example implementations, solder bumps 40 may be attached to surface S1 (i.e., to the redistribution layer (e.g., RDL 16-1)) for external electrical connections (e.g., via a printed circuit board (PCB) (not shown)) to stacked optical sensor package 100.

In example implementations, a through mold via (TMV) (e.g., TMV 18) extending across layer A between surface S1 and surface S2 may provide a passage for connections between the two redistribution layers to the redistribution layer (e.g., RDL 16-1 and RDL 16-2).

In example implementations, ISP die 10 may be attached to surface S2 (i.e., to the redistribution layer (e.g., RDL 16-2)) (and to optical sensor die 20, layer B) with a die bonding adhesive (e.g., die bonding adhesive 14). The die bonding adhesive may, for example, be a thermosetting polymer such as epoxies, acrylics, bismaleimides and polyimides.

In stacked optical sensor package 100, optical sensor die 20 in layer B is disposed above (e.g., in the z direction) ISP die 10. Optical sensor die 20 (having a width W2 and a height H2) may be a portion of a semiconductor wafer (e.g., silicon wafer 50). A passivation layer (e.g., layer 22) (e.g., an oxide or a nitride layer) may be grown or deposited on a bottom surface (e.g., surface S3) of silicon wafer 50. Optical sensor die 20 may include an active region 20A disposed on a top surface (e.g., surface S4) of the die. Active area 20A may, for example, include active pixels, color filters and/or micro lens assemblies, etc., for imaging with optical sensor die 20. Active area 20A may have a height AH above the top surface (e.g., surface S4) of the die.

In example implementations of stacked optical sensor package 100, optical sensor die 20 in layer B is disposed over ISP die 10 on the redistribution layer (e.g., RDL 16-2) of layer A with the passivation layer (e.g., layer 22) on surface S3 coupled to the redistribution layer (e.g., RDL 16-2) on surface S2.

In example implementations of stacked optical sensor package 100, optical sensor die 20 in layer B may be isolated from other portions of semiconductor wafer 50 by through-semiconductor vias (e.g., TSV 24) extending between surface S4 and surface S2 through height H2 of the die. In example implementations, TSV 24 may be lined with a passivation layer (e.g., layer 22).

Further, in example implementations, a sheet of transparent material (e.g., cover glass 30) is disposed (in layer C) over optical sensor die 20. The sheet of transparent material may be made of any transparent material (e.g., glass, plastics, etc.). The sheet of transparent material may be transparent to light (e.g., visible light) directed to active region 20A of optical sensor die 20 for imaging.

In example implementations, a dam material (e.g., an epoxy or resin, etc.) may be used to bond the sheet of transparent material (e.g., cover glass 30) to optical sensor die 20. The dam material may, for example, be disposed as a dam layer 32 around a periphery (P) of active region 20A (i.e., outside of edges E of the active region) disposed on the top surface (e.g., surface S4) of the die. In example implementations, dam layer 32 may have a thickness GH (in the z direction) which is greater than the thickness AH of active area 20A above the top surface (0078 of the die. This thickness (i.e., thickness GH>thickness AH) of dam layer 32 may create an air gap (e.g., air gap 34) between glass cover 30 and optical sensor die 20.

In some example implementations, the dam material may be used to fill all of the space between glass cover 30 and optical sensor die 20 resulting in a gapless (i.e., without an air gap) optical sensor package. FIG. 1B shows a cross sectional view (in a z-x plane) of an example gapless stacked optical sensor package (e.g., stacked optical sensor package 100B), in accordance with the principles of the present disclosure. As shown in FIG. 1B, the dam material (i.e., dam layer 32) fills all the space between glass cover 30 and optical sensor die 20 resulting in a gapless (i.e., without an air gap) stacked optical sensor package. For example, as shown in FIG. 1B, in stacked optical sensor package 100B, dam layer 32 fills all of the air gap 34 that is present in stacked optical sensor package 100 shown in FIG. 1A.

In some example implementations, a black coating may be applied to side surfaces of stacked optical sensor package 100 to prevent or reduce the amount of light reaching the semiconductor material in the package other than the intended active region (i.e., active region 20A of optical sensor die 20) for imaging. In some example implementations, a black paint or coating may be applied to the vertical sides of stacked optical sensor package 100. In some example implementations, a black paint or coating may be applied to an edge strip on a top surface of the glass cover in addition to the black paint or coating applied to the vertical sides of stacked optical sensor package 100.

FIG. 1C shows an example stacked optical sensor package 100C, in accordance with the principles of the present disclosure. In example stacked optical sensor package 100C, a black coating 70 is applied to vertical sides (VS) (that are parallel to the z direction) of the package.

FIG. 1D shows an example stacked optical sensor package 100D, in accordance with the principles of the present disclosure. In example stacked optical sensor package 100D, a black coating 72 is applied to an edge strip (ES) on a top surface S5 of cover glass 30 (in addition to black coating 70 applied to vertical sides VS). In example implementations, the black coating 70 applied to vertical sides VS and the black coating 72 applied to edge strip ES on top surface S5 of cover glass 30 may be the same molding material as the molding material 12 used in layer A of stacked optical sensor package 100 to embed ISP 10.

FIG. 1E shows an example stacked optical sensor package 100E, in accordance with the principles of the present disclosure. In example stacked optical sensor package 100E, a black coating 72 is applied to edge strip ES on a top surface S5 of cover glass 30. Unlike stacked optical sensor package 100D (FIG. 1D) no black coating 70 is applied to vertical sides VS of stacked optical sensor package 100E.

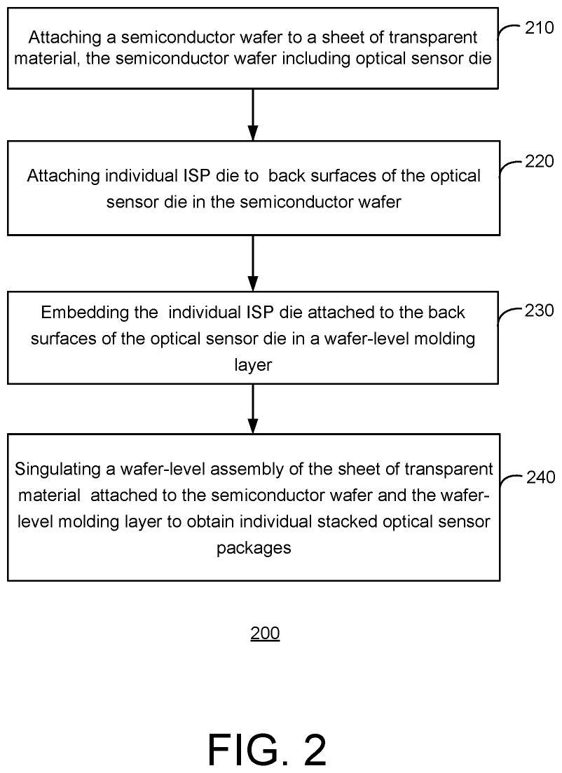

FIG. 2 shows an example method 200 for fabricating a stacked chip scale optical sensor package (e.g., stacked optical sensor package 100, FIG. 1A).

Method 200 involves wafer-level chip scale packaging with the top and bottom outer layers of the packaging and solder bumps attached to the package while the optical sensor dies are still in the wafer, and then dicing (singulating) the wafer. In example implementations, a glass cover sheet is used a starting substrate to support a stack of a semiconductor wafer including optical sensor die and a wafer-level molding layer including embedded individual ISP die. The wafer-level molding layer can include fan out of electrical routing from the ISP die.

As shown in FIG. 2, method 200 may include attaching a semiconductor wafer including optical sensor die to a sheet of transparent material (210), attaching individual ISP die to back surfaces of the optical sensor die in the semiconductor wafer (220), embedding the individual ISP die attached to the back surfaces of the optical sensor die in the semiconductor wafer in a wafer-level molding layer (230), and singulating a wafer-level assembly of the sheet of transparent material, the semiconductor wafer, and the wafer-level molding layer to obtain individual stacked optical sensor packages (240). The wafer-level assembly is formed by attaching the semiconductor wafer to the sheet of transparent material and embedding the individual ISP die attached to the back surfaces of the optical sensor die in the semiconductor wafer in the wafer-level molding layer.

In method 200, attaching the semiconductor wafer including the optical sensor die to the sheet of transparent material 210 includes attaching the semiconductor wafer to a glass cover, and thinning a back side of the semiconductor wafer attached to the glass cover.

Attaching the semiconductor wafer including the optical sensor die to the sheet of transparent material 210 may further include forming through-semiconductor vias (TSVs) at edges of the optical sensor dies from the back side of the thinned semiconductor wafer, passivating a back surface of the die including the TSVs, and forming a first signal redistribution layer (RDL) on a back surface of the semiconductor wafer including the optical sensor die.

In method 200, embedding the individual ISP die attached to the back surfaces of the optical sensor die in a wafer-level molding layer 230 may include forming through-mold vias (TMVs) through the wafer-level molding layer and forming a second redistribution layer (RDL) on a back surface of the wafer-level molding layer including the individual embedded ISP die.

Method 200 may further include coating the sides (vertical sides) of the individual stacked optical sensor packages with black material, and/or coating an edge strip of the cover glass of the individual stacked optical sensor packages with black material.

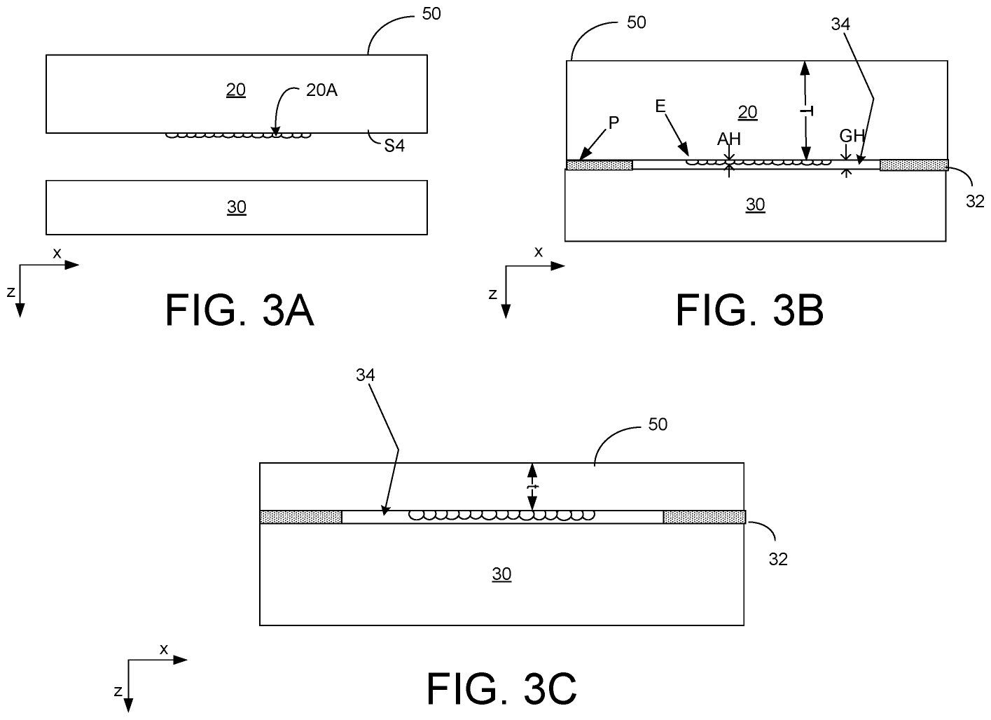

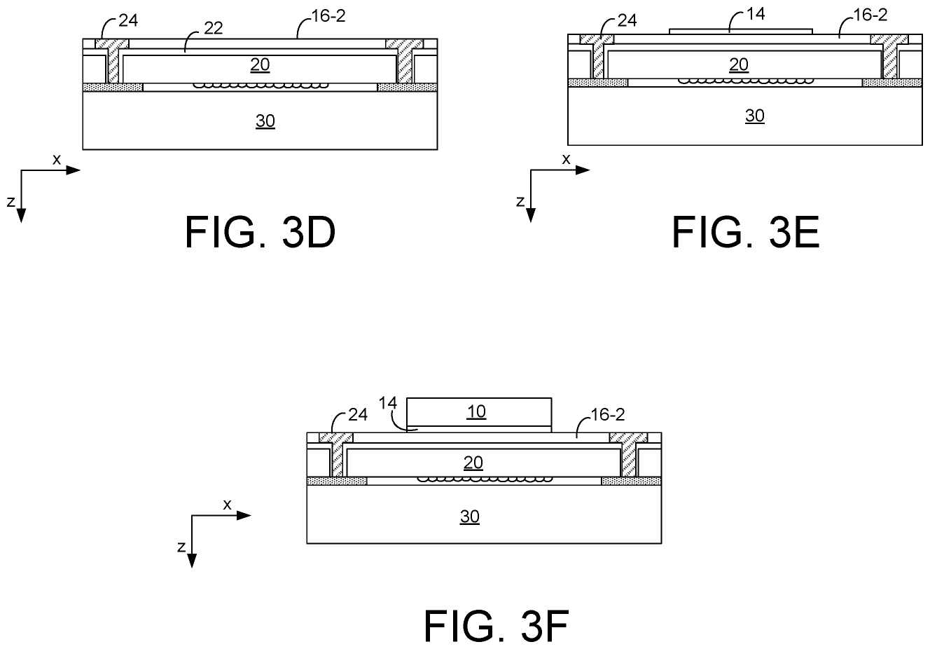

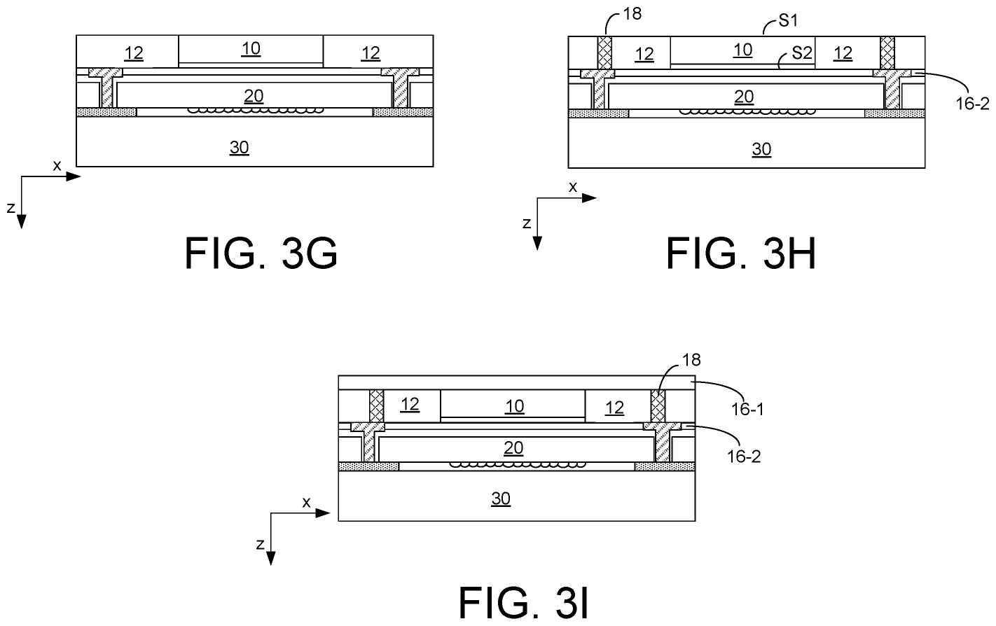

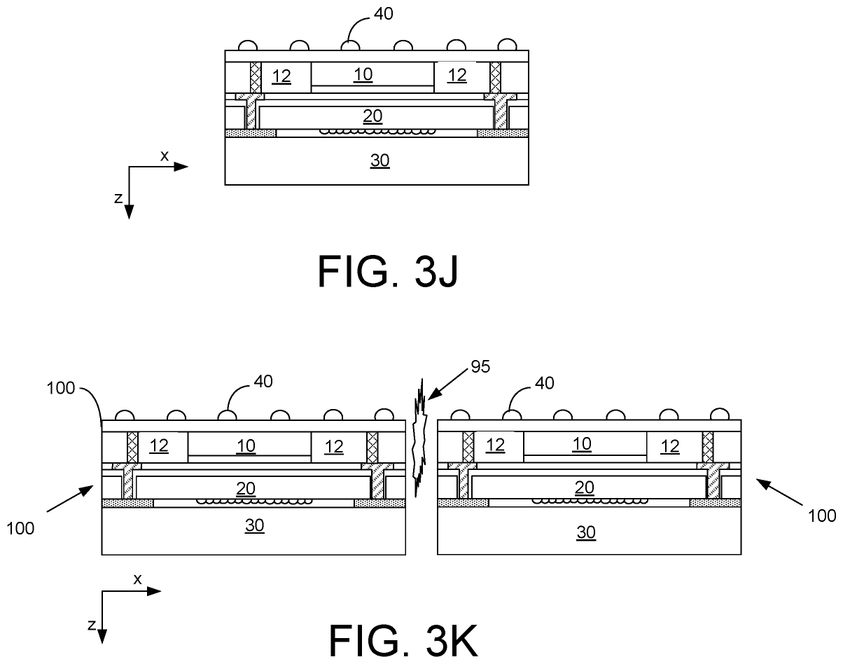

FIGS. 3A through 3K schematically illustrate a multi-die optical sensor package (e.g., stacked optical sensor package 100, FIG. 1A) at different stages of construction on a substrate (e.g., glass cover 30), or after the different steps of method 200 for fabricating a stacked chip scale optical sensor package. FIGS. 3A through 3K show cross-sectional views of the stacked chip scale optical sensor package at the different stages of construction.

FIG. 3A shows an example substrate (i.e., a sheet of transparent material) (e.g., cover glass 30) and a semiconductor wafer 50 that can be used for fabricating a stacked chip scale optical sensor package (e.g., stacked optical sensor package 100) at a first stage of construction (e.g., in method 200, before step 210). As described previously semiconductor wafer 50 (e.g., a silicon wafer) may include several optical sensor die 20 (e.g., CIS die). Each of the optical sensor die 20 may have an (optically) active area 20A exposed on a top surface (e.g., surface S4) of semiconductor wafer 50. The sides of optical sensor die 20 with the optically active areas can be referred to herein as the front sides of the die and/or the front side of the semiconductor wafer. The side opposite the front side can be referred to herein as the back side of the optical sensor die or the semiconductor wafer.

The semiconductor wafer may have a thickness T (FIG. 3B). Thickness T for a silicon wafer can be, depending on the diameter of the wafer, 300 μm or greater.

FIG. 3B show the stacked chip scale optical sensor package at a second stage of construction (e.g., method 200, step 210) with semiconductor wafer 50 placed (front side down in the −z direction) on, and bonded to, the sheet of transparent material (e.g., cover glass 30). Semiconductor wafer 50 and cover glass 30 may be bonded to each other using, for example, a non-conductive epoxy or polymer. The non-conductive epoxy or polymer may be applied as a dam material layer. The dam material may, for example, be disposed as a dam layer 32 around a periphery P of active region 20A (i.e., outside of edges E of the active region) disposed on the top surface (e.g., surface S4) of the die. In example implementations, dam layer 32 may have a thickness GH in a range of several μm to several hundred μm (e.g., 40 um). The thickness GH (e.g., 40 μm) of dam layer 32 can be greater than the thickness AH of active area 20A above the top surface S4 of the die. The thickness GH being greater than the thickness AH may create an air gap (e.g., air gap 34) between glass cover 30 and optical sensor die 20.

In some example implementations, as previously mentioned, the dam material may be used to fill all the space between glass cover 30 and optical sensor die 20 resulting in a gapless (i.e., without an air gap) stacked optical sensor package (e.g., stacked optical sensor package 100B, FIG. 1B).

In example implementations, a process for bonding semiconductor wafer and cover glass 30 to each other may include a heat treatment phase (e.g., 120° C. for min) after application of dam material layer 32 to the periphery P, followed by a curing phase (e.g., 150° C. for 4 hrs.).

FIG. 3C shows the stacked chip scale optical sensor package at a third stage of construction. In this stage of construction, after bonding semiconductor wafer 50 and cover glass 30, semiconductor wafer 50 may be thinned down from its original or starting thickness T to a smaller thickness t. The thinned down thickness t may, for example, be in a range of about 50 μm to 200 μm (e.g., 100 μm). Back grinding and/or chemo-mechanical polishing techniques may be used to thin the semiconductor wafer.

FIG. 3D shows the stacked chip scale optical sensor package at a third stage of construction. At this stage of construction, a through semiconductor via (e.g., TSV 24) may be etched through the thickness t of thinned semiconductor wafer 50. The TSV may provide electrical connections (not shown) between a front side of optical sensor die 20 and a back side of the die. Further, at this stage of construction, exposed surfaces of semiconductor wafer 50 may be passivated with a passivation layer 22 (e.g., an oxide and/or a nitride layer). Further, a (signal) redistribution layer (e.g., RDL 16-2) may be formed on the passivation layer 22. RDL 16-2 may include conductive traces and contact pads (not shown) for making electrical connections and routing electrical signals between elements of the stacked chip scale optical sensor package.

In example implementations, TSV 24 may have a diameter in a range from several μm to several tens of μm (e.g., 50 μm) and a depth corresponding to the thickness t (e.g., 100 μm) of the thinned semiconductor wafer. TSV 24 may be formed by plasma etching or laser drilling, followed by formation of the passivation layers (passivation layer 22) and metallization (e.g., RDL 16-2). The metallization in RDL 16-2 may include conductive traces and contact pads made of metals such as titanium (Ti), copper (Cu), aluminum (Al), or nickel (Ni), or alloys thereof.

FIGS. 3E and 3F relate to the fourth and fifth stages of construction in which individual ISP dies positioned and bonded to RDL 16-2 above the optical sensor die 20 (or bonded to the optical sensor die 20 across RDL 16-2). FIGS. 3E shows a layer of a die bonding adhesive (e.g., die bonding adhesive 14) disposed on RDL 16-2 directly above (in the −z direction) or on the back side of optical sensor die 20 (i.e., on the back side of the thinned semiconductor wafer 50). Die bonding adhesive 14 may, for example, be an epoxy or a die attach film (DAF). In example implementations, die bonding adhesive 14 may have a thickness in a range of several μm to several tens of μm (e.g., 10 μm).

FIG. 3F shows an individual ISP die 10 placed on the layer of die bonding adhesive (e.g., die bonding adhesive 14) and bonded to the back side of optical sensor die 20. In example implementations, an individual ISP die 10 may positioned on die bonding adhesive 14 on the back side of the semiconductor wafer 50 by a pick-and-place tool. In example implementations, die bonding adhesive 14 may have a thickness in a range of several μm to several tens of μm (e.g., 10 μm).

FIG. 3G shows the stacked chip scale optical sensor package at a sixth stage of construction. At this stage, a molding material may be applied to the back side of the semiconductor wafer 50 above RDL layer 16-2 so that the individual ISP die 10 bonded to the back side of the semiconductor wafer 50 are embedded in a layer of molding material (e.g., molding material 12). The molding material may, for example, be a liquid molding compound (LMC) or an epoxy mold compound (EMC). Either transfer mold or compression mold processes may be used to form the layer of molding material (e.g., molding material 12) embedding the individual ISP die 10 on the back side of the semiconductor wafer 50.

FIG. 3H shows the stacked chip scale optical sensor package at a seventh stage of construction. At this stage of construction, a through mold via (TMV) (e.g., TMV 18) may be etched through the layer of molding material (e.g., molding material 12) between a front surface (e.g., surface S1) and a back surface (e.g., surface S2) of the layer of molding material. TMV 18 may be formed by plasma etching or laser drilling. TMV 18 may provide electrical connections (not shown) across the layer of molding material (e.g., molding material 12) between a front side (e.g., surface S1) of the individual ISP die 10 and the RDL layer (e.g., RDL layer 16-2) disposed on the backside of optical sensor die 20.

FIG. 3I shows the stacked chip scale optical sensor package at an eight stage of construction. At this stage of construction, a (signal) redistribution layer (e.g., RDL 16-1) may be formed on the front surface (e.g., surface S1) of the layer of molding material (e.g., molding material 12) and the individual the individual ISP die 10. RDL 16-1 may include conductive traces and contact pads (not shown) for making electrical connections and routing electrical signals between elements of the stacked chip scale optical sensor package, and to and from outside the stacked chip scale optical sensor package. The metallization in RDL 16-1 (like in RDL 16-2) may include conductive traces and contact pads made of metals such as titanium (Ti), copper (Cu), aluminum (Al), or nickel (Ni), or alloys thereof.

FIG. 3J shows the stacked chip scale optical sensor package at a ninth stage of construction. At this stage of construction, conductive bumps (e.g., solder bumps 40) may be attached to surface S1 (i.e., to the redistribution layer (e.g., RDL 16-1)) for external electrical connections (e.g., via a printed circuit board (PCB) (not shown)) to stacked optical sensor package 100. The conductive bumps (e.g., solder bumps 40) may be applied in a wafer-level bumping process.

In example implementations, the conductive bumps (e.g., solder bumps 40) may be composed of solder or lead-free solder. In some example implementations, the conductive bumps may be composed of copper (e.g., copper balls or pillars, or copper pillars capped with solder).

Next, as shown in FIG. 3K, the foregoing assembly of the layer of molding material (e.g., molding material 12 with embedded ISP die 10) disposed on top the semiconductor wafer (e.g., semiconductor wafer 50 including the optical sensor die 20), and the sheet of a transparent material (e.g., cover glass 30) may be singulated to produce individual chip scale packages (CSP) (e.g., stacked optical sensor package 100). Each individual CSP (e.g., stacked optical sensor package 100) may include a single optical sensor die 20 (formed in a singulated portion of semiconductor wafer 50) and a single ISP die 10.

In FIG. 3K, for purposes of illustration, the singulation process is shown by a pictorial representation of a saw 95.

While certain features of the described implementations have been illustrated as described herein, many modifications, substitutions, changes, and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

It will be understood that, in the foregoing description, when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Unless defined otherwise, all technical and scientific terms used herein have the same meaning as commonly understood by one of ordinary skill in the art. Methods and materials similar or equivalent to those described herein can be used in the practice or testing of the present disclosure. As used in the specification, and in the appended claims, the singular forms “a,” “an,” “the” include plural referents unless the context clearly dictates otherwise. The term “comprising,” and variations thereof as used herein is used synonymously with the term “including” and variations thereof and are open, non-limiting terms. The terms “optional” or “optionally” used herein mean that the subsequently described feature, event or circumstance may or may not occur, and that the description includes instances where said feature, event or circumstance occurs and instances where it does not. Ranges may be expressed herein as from “about” one particular value, and/or to “about” another particular value. When such a range is expressed, an aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

What is claimed is:

1. A package comprising:
a semiconductor wafer including an optical sensor die, the optical sensor die having an optically active area on a front side of the semiconductor wafer generating a raw image signal;
a transparent cover attached to the front side of the semiconductor wafer, the transparent cover disposed above the optically active area of the optical sensor die in the semiconductor wafer; and
an image signal processor (ISP) die embedded in a layer of molding material, the layer of the molding material attached to the semiconductor wafer on a back side opposite the front side of the semiconductor wafer, the ISP die processing the raw image signal.

2. The package of claim 1, further comprising:
a first signal redistribution layer disposed on a first surface of the layer of the molding material corresponding to an outer surface of the package.

3. The package of claim 2, further comprising, a conductive bump disposed on the first signal redistribution layer disposed on the first surface of the layer of the molding material corresponding to the outer surface of the package.

4. The package of claim 3, wherein the conductive bump disposed on the first signal redistribution layer disposed on the first surface of the layer of the molding material corresponding to the outer surface of the package includes at least one of a solder bump, a copper ball, a copper pillar, or a solder-capped copper pillar.

5. The package of claim 2, further comprising:
a second signal redistribution layer disposed the back side of the semiconductor wafer, the back side of the semiconductor wafer being adjacent to a second surface of the layer of the molding material opposite the first surface of the layer of the molding material.

6. The package of claim 5, wherein the image signal processor (ISP) die embedded in the layer of the molding material is positioned across from the optical sensor die in the semiconductor wafer and is bonded to the second signal redistribution layer disposed the back side of the semiconductor wafer.

7. The package of claim 5, further comprising:
a through-mold via (TMV) extending through a thickness of the layer of the molding material between the first surface of the layer of the molding material and the second surface of the layer of the molding material.

8. The package of claim 5, further comprising:
a through-semiconductor via (TSV) extending through a thickness of the semiconductor wafer, the TSV providing electrical connections between a front side of the optical sensor die and a back side of the optical sensor die.

9. The package of claim 1, wherein the transparent cover attached to the front side of the semiconductor wafer is a glass cover.

10. The package of claim 9, wherein the transparent cover is attached to the front side of the semiconductor wafer by a dam material layer disposed around a periphery of the optically active area of the optical sensor die.

11. The package of claim 10, further comprising an air gap between the transparent cover and the front side of the semiconductor wafer.

12. The package of claim 1, further comprising:
a black coating disposed on a side of a stack formed by the semiconductor wafer including the optical sensor die, the transparent cover bonded to the front side of the semiconductor wafer, and the layer of the molding material attached to the semiconductor wafer.

13. The package of claim 1, further comprising:
a black coating disposed on an edge strip on a top surface of the transparent cover bonded to the front side of the semiconductor wafer.

14. A method, comprising:
attaching a semiconductor wafer to a sheet of transparent material, the semiconductor wafer including a plurality of optical sensor dies;
attaching a plurality of individual image signal processor (ISP) dies to back surfaces of the plurality of the optical sensor dies in the semiconductor wafer;
embedding the plurality of the individual ISP dies attached to the back surfaces of the plurality of the optical sensor dies in a wafer-level molding layer; and
singulating a wafer-level assembly of the sheet of the transparent material attached to the semiconductor wafer and the wafer-level molding layer to produce at least one individual stacked optical sensor package.

15. The method of claim 14, wherein the sheet of the transparent material is a glass cover.

16. The method of claim 14, wherein attaching the semiconductor wafer including the plurality of optical sensor dies to the sheet of the transparent material includes thinning a back side of the semiconductor wafer.

17. The method of claim 14, wherein attaching the semiconductor wafer including the plurality of the optical sensor dies to the sheet of the transparent material includes forming a through-semiconductor vias (TSV) at at least one edge of the optical sensor dies from a back side of the semiconductor wafer.

18. The method of claim 17, wherein attaching the semiconductor wafer including the plurality of optical sensor dies to the sheet of the transparent material includes forming a first signal redistribution layer (RDL) on a back surface of the semiconductor wafer including the plurality of the optical sensor dies.

19. The method of claim 14, wherein embedding the plurality of the individual ISP dies attached to the back surfaces of the plurality of the optical sensor dies in the wafer-level molding layer includes forming through-mold vias (TMVs) through the wafer-level molding layer.

20. The method of claim 14, wherein embedding the plurality of the individual ISP dies attached to the back surfaces of the plurality of the optical sensor dies in the wafer-level molding layer includes forming a second signal redistribution layer (RDL) on a back surface of the wafer-level molding layer including the individual ISP die.

21. The method of claim 20, further comprising:
attaching conductive bumps to the second signal redistribution layer (RDL) on the back surface of the wafer-level molding layer.
